(19) United States
(12) Patent Application Publication
(10) Pub. No.: US 2003/0027403 A1
(43) Pub. Date: Feb. 6, 2003

(54) Method for forming sacrificial oxide layer

(75) Inventor: Shu-Ya Hsu, Yun-Lin (TW)

Correspondence Address: LOWE HAUPTMAN GILMAN & BERNER, LLP, Suite 310, 1700 Diagonal Road, Alexandria, VA, 22314, US

(73) Assignee: MACRONIX INTERNATIONAL CO., LTD.

(21) Appl. No.: 09/920,634

(22) Filed: Aug. 3, 2001

(51) Int. Cl. H01L 21/76

(52) U.S. Cl. 438/424

(57) ABSTRACT

A method for forming a sacrificial oxide layer is disclosed. The invention utilizes an in situ steam generated process comprising the introductions of oxygen and hydroxyl to oxidize active regions of a substrate and form a sacrificial oxide layer. The ISSG process renders the sacrificial oxide layer much less stress and encroachment. Unlike the conventional sacrificial oxide layer, the sacrificial oxide layer formed by the method set forth will not damage the substrate. The electrical and mechanical properties of the active regions can be assured.

### BACKGROUND OF THE INVENTION

1. Field of the Invention

The present invention relates to a method for forming a sacrificial layer, and more particularly to a method for forming a sacrificial layer with reduced stress.

2. Description of the Related Art

Conventional oxidation processes are widely used in manufacture of semiconductor devices to form oxide layers for various purposes. For example, conventional oxide layers such as pad oxide layers, buffer layers, gate oxide layers and sacrificial oxide layers are formed by conventional oxidation processes. It is well known that the oxide layer formed by conventional thermal oxidation process has superior electrical and mechanical properties. However, the oxide layer formed by conventional thermal oxidation processes also has several drawbacks such as stress issues and the long processing time. The stress issues will damage the underlying substrate and degrade the reliability of following formed devices and the long processing time will not meet the requirements of modern semiconductor process. The issues have become more and more considerable for the provisional oxide layers such as sacrificial oxide layers, pad oxide layers and buffer oxide layers. These oxide layers are removed as their functions achieved, but the problems these provisional oxide layers induced will remain. FIG. 1 shows a cross-sectional diagram of a conventional sacrificial oxide layer 104 formed over a substrate 100 having shallow trench isolations 102a and 102b therein. The sacrificial oxide layer 104 formed by conventional oxidation processes is used to prevent the channel effect resulting from the sequential ion implantation, but the conventional oxidation process also presents the substrate 100 with large stress and defects. After the ion implantation, the sacrificial oxide layer 104 is removed by conventional etching, but the stress and defects still remain. This stress and defects not only damage the active region of the substrate 100, but also degrade the reliability of the following formed devices on the active region. Moreover, the processing time of the conventional oxidation process spent to form a conventional sacrificial oxide layer is also time-consuming. Accordingly, the sacrificial oxide layer formed by conventional oxidation processes will not meet the requirements of modern semiconductor processes.

In view of the drawbacks mentioned with the prior art process, there is a continued need to develop new and improved processes that overcome the disadvantages associated with prior art processes. The requirements of this invention are that it solves the problems mentioned above.

### SUMMARY OF THE INVENTION

It is therefore an object of the invention to provide a method for forming a sacrificial oxide layer with reduced stress.

It is another object of this invention to provide a process for forming a sacrificial oxide layer which can assure the electrical property of the active regions.

It is a further object of this invention to provide a reliable process for forming a sacrificial oxide layer which can assure the reliability of devices in the active regions.

It is another object of this invention to provide a process for forming a sacrificial oxide layer with a shorter process time.

To achieve these objects, and in accordance with the purpose of the invention, the invention uses a method comprising: providing a substrate having isolation regions therein; and forming a sacrificial oxide layer over said substrate by an in situ steam generated process comprising introducing oxygen and hydroxyl.

It is to be understood that both the foregoing general description and the following detailed description are exemplary and explanatory only and are not restrictive of the invention, as claimed.

### BRIEF DESCRIPTION OF THE DRAWINGS

FIG. 1 shows a cross-sectional diagram of a conventional sacrificial oxide layer formed over a substrate having shallow trench isolations therein;

FIG. 2A shows two dielectric layers sequentially formed over a substrate having shallow trench isolations therein;

FIG. 2B shows a result of removing the dielectric layers shown in FIG. 2A;

FIG. 2C shows a result of forming a sacrificial oxide layer of this invention; and

FIG. 3 shows a schematic diagram of a process system.

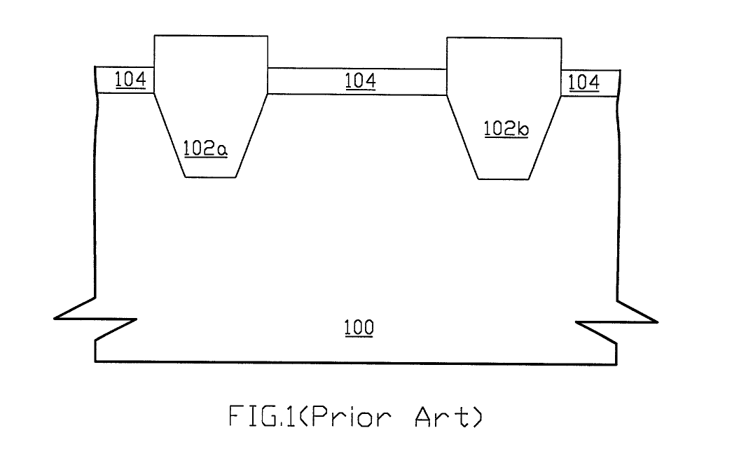

The foregoing aspects and many of the attendant advantages of this invention will become more readily appreciated as the same becomes better understood by reference to the following detailed description, when taken in conjunction with the accompanying drawings, wherein:

### DESCRIPTION OF THE PREFERRED EMBODIMENT

It is to be understood and appreciated that the process steps and structures described below do not cover a complete process flow. The present invention can be practiced in conjunction with various integrated circuit fabrication techniques that are used in the art, and only so much of the commonly practiced process steps are included herein as are necessary to provide an understanding of the present invention.

The present invention will be described in detail with reference to the accompanying drawings. It should be noted that the drawings are in greatly simplified form and they are not drawn to scale. Moreover, dimensions have been exaggerated in order to provide a clear illustration and understanding of the present invention.

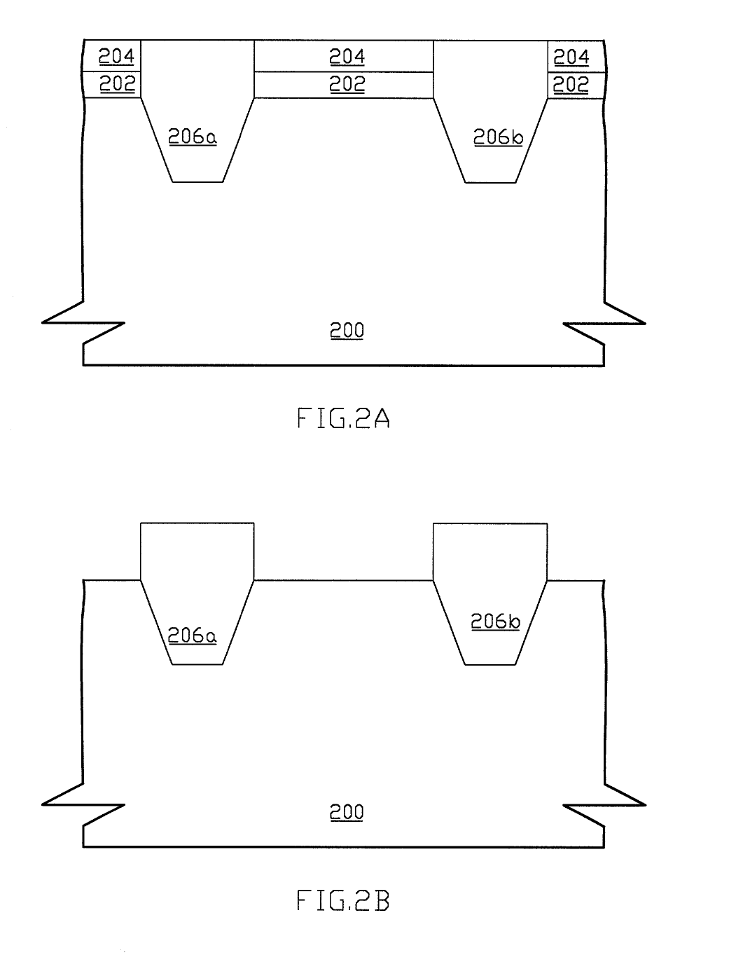

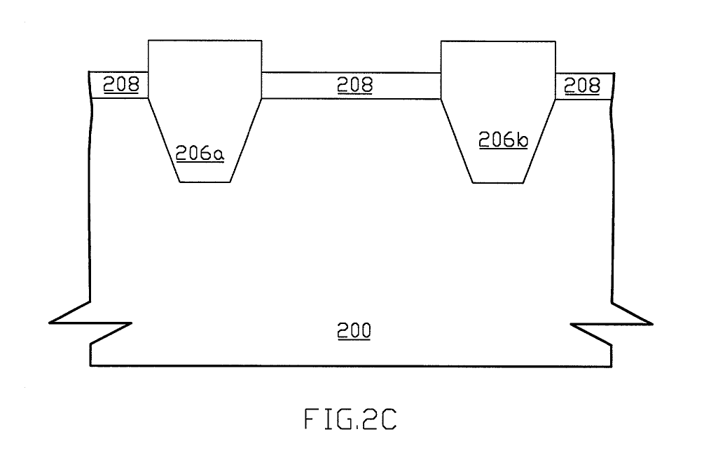

Referring to FIG. 2A, dielectric layers 202 and 204 are sequentially formed over a substrate 200. The substrate 200 preferably comprises, but is not limited to: a silicon substrate with a <100> crystallographic orientation. The substrate can also comprise other semiconductor substrate such as a SOI (Silicon On Insulator)substrate. The dielectric layer 202 preferably comprises, but is not limited to: a silicon dioxide layer formed by a thermal growth process. The dielectric layer 202 has a thickness of from about 20 angstrom to about 300 angstrom. The dielectric layer 204 preferably comprises a silicon nitride layer formed by conventional methods such as chemical vapor deposition, but other material met the spirit of this invention should not be excluded. The silicon nitride layer 204 preferably has a thickness of from about 100 angstrom to about 2000 angstrom. Also as shown in FIG. 2A, shallow trench isolations 206a and 206b are formed by conventional methods such as etching and chemical vapor deposition. The shallow trench isolations 206a and 206b preferably comprise silicon dioxide layers formed by conventional chemical vapor deposition processes such as low pressure chemical vapor deposition (LPCVD), atmosphere pressure chemical vapor deposition (APCVD) and high density plasma chemical vapor deposition (HDPCVD). It is noted that the shallow trench isolations 206a and 206b set forth are just examples, other isolations such as field oxide regions (FOX) by conventional local oxidation of silicon (LOCOS) methods should not be excluded.

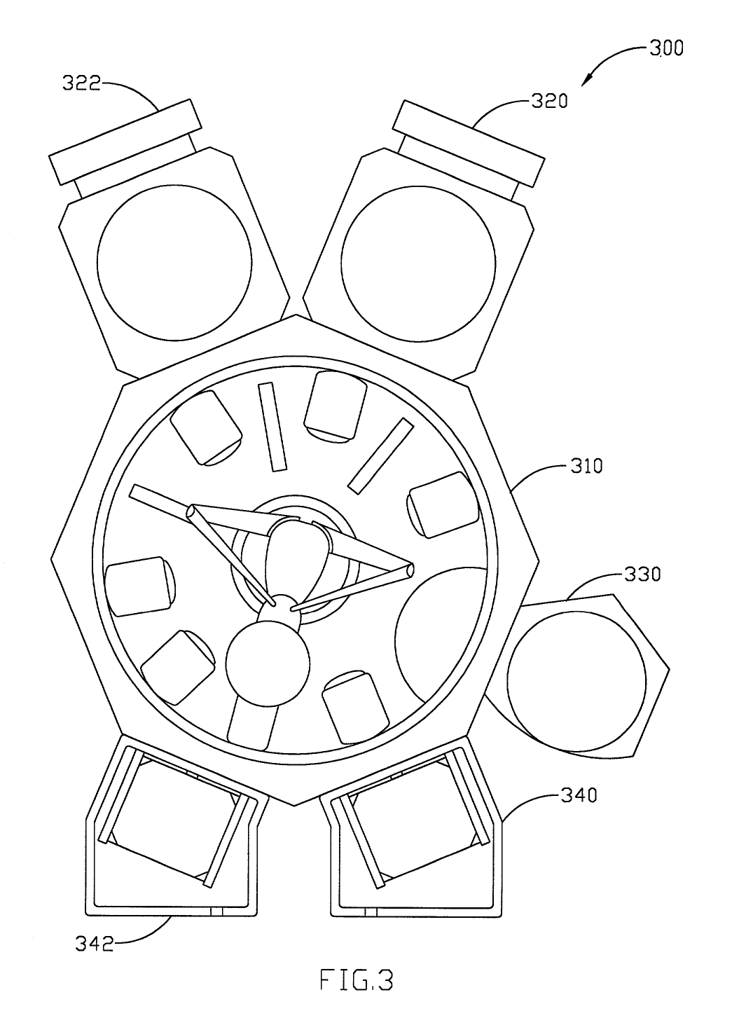

Referring to FIG. 2B, the dielectric layers 202 and 204 are removed by conventional methods such as wet etching. The substrate 200 is then cleaned by conventional methods such as RCA clean. The substrate 200 then is oxidized by using an in situ steam generated process. The in situ steam generated process can be performed in a conventional furnace, but is preferably in a rapid thermal processing (RTP)chamber and specially in a single wafer RTP chamber. There are numerous processing equipment can be used to perform an ISSG process. FIG. 3 shows a Centura® 5000 system 300 marketed by the Applied Materials Corporation. A rapid thermal processing chamber 320 is bolted to a vacuum transfer chamber 310. There are also a process chamber 322, a cool down chamber 330 and vacuum cassette loadlocks 340 and 342 bolted to the vacuum transfer chamber 310. The substrate 200 is oxidized in an atmosphere comprising oxygen and hydrogen and at a temperature between about 700° C. to about 1200° C. The flow rate of oxygen is from about 1 sccm (Standard Cubic Centimeter per Minute) to about 30 sccm, and the flow rate of hydroxyl is from about 0.1 sccm to about 15 sccm. The processing time of this ISSG process is from about 1 minute to about 10 minute. FIG. 2C shows the result of oxidizing the substrate 200 to form a sacrificial oxide layer 208. The thickness of the sacrificial oxide layer 208 is from about 30 angstrom to about 300 angstrom.

The invention utilizes an in situ steam generated process comprising the introductions of oxygen and hydroxyl to oxidize active regions of a substrate and form a sacrificial oxide layer. The ISSG process renders the sacrificial oxide layer much less stress and encroachment and the ISSG process expends much less process time. Unlike the conventional sacrificial oxide layer, the sacrificial oxide layer formed by the method set forth will not damage the substrate. The electrical and mechanical properties of the active region can be assured.

Other embodiments of the invention will appear to those skilled in the art from consideration of the specification and practice of the invention disclosed herein. It is intended that the specification and examples to be considered as exemplary only, with a true scope and spirit of the invention being indicated by the following claims.

What is claim is:

1. A method for forming a sacrificial oxide layer, said method comprising:
providing a substrate having isolation regions therein; and
forming a sacrificial oxide layer over said substrate by an in situ steam generated process comprising introducing oxygen and hydroxyl.

2. The method according to claim 1, wherein said substrate comprises a silicon substrate.

3. The method according to claim 1, wherein said isolation region comprises a shallow trench isolation.

4. The method according to claim 1, wherein said in situ steam generated process is performed in a rapid thermal processing chamber.

5. The method according to claim 1, wherein said in situ steam generated process is performed at a temperature of from about 700° C. to about 1200° C.

6. The method according to claim 1, wherein the flow rate of oxygen is from about 1 sccm to about 30 sccm.

7. The method according to claim 1, wherein the flow rate of hydrogen is from about 0.1 sccm to about 15 sccm.

8. The method according to claim 4, wherein said rapid thermal processing chamber comprises a single wafer chamber.

9. A method for forming a sacrificial oxide layer, said method comprising:
providing a substrate having isolation regions therein; and
forming a sacrificial oxide layer over said substrate by an in situ steam generated process comprising introducing oxygen and hydroxyl performed at a temperature of from about 700° C. to about 1200° C.

10. The method according to claim 9, wherein said substrate comprises a silicon substrate.

11. The method according to claim 9, wherein said isolation region comprises a shallow trench isolation.

12. The method according to claim 9, wherein said in situ steam generated process is performed in a rapid thermal processing chamber.

13. The method according to claim 9, wherein the flow rate of oxygen is from about 1 sccm to about 30 sccm.

14. The method according to claim 9, wherein the flow rate of hydrogen is from about 0.1 sccm to about 15 sccm.

15. The method according to claim 12, wherein said rapid thermal processing chamber comprises a single wafer chamber.

16. A method for forming a sacrificial oxide layer, said method comprising:
providing a substrate having isolation regions therein; and
forming a sacrificial oxide layer over said substrate by an in situ steam generated process comprising introducing oxygen and hydroxyl performed in a rapid thermal processing chamber at a temperature of from about 700° C. to about 1200° C.

17. The method according to claim 16, wherein the flow rate of oxygen is from about 1 sccm to about 30 sccm.

18. The method according to claim 16, wherein the flow rate of hydrogen is from about 0.1 sccm to about 15 sccm.
